(19) United States
(12) Patent Application Publication
(10) Pub. No.: US 2023/0301047 A1
(43) Pub. Date: Sep. 21, 2023

(54) ELECTROMAGNETIC WAVE ABSORBING SHEET

(71) Applicants: PANASONIC HOLDINGS CORPORATION, Osaka (JP); THE UNIVERSITY OF TOKYO, Tokyo (JP)

(72) Inventors: Keiko KASHIHARA, Osaka (JP); Rei FUJIWARA, Osaka (JP); Shin-ichi OHKOSHI, Tokyo (JP); Asuka NAMAI, Tokyo (JP)

(73) Assignees: PANASONIC HOLDINGS CORPORATION, Osaka (JP); THE UNIVERSITY OF TOKYO, Tokyo (JP)

(21) Appl. No.: 18/137,142

(22) Filed: Apr. 20, 2023

Related U.S. Application Data
(63) Continuation of application No. PCT/JP2021/039609, filed on Oct. 27, 2021.

(30) Foreign Application Priority Data
Oct. 27, 2020 (JP) 2020-179850

(51) Int. Cl. H05K 9/00; H01Q 17/00; B32B 27/36; B32B 27/08; B32B 15/20; B32B 15/09

(52) U.S. Cl. CPC H05K 9/0081; B32B 15/09; B32B 15/20; B32B 27/08; B32B 27/36; H01Q 17/00; B32B 2255/10; B32B 2255/20; B32B 2307/204; B32B 2307/212; B32B 2605/00

(57) ABSTRACT

An electromagnetic wave absorbing sheet includes a metallic base and an electromagnetic wave absorption film formed on the metallic base. The electromagnetic wave absorption film contains MTC-substituted ε—Fe₂O₃, black titanium oxide, a conductive filler, and a resin. The MTC-substituted ε—Fe₂O₃ is a crystal belonging to the same space group as an ε—Fe₂O₃ crystal and containing Ti, Co, Fe, and at least one element selected from the group consisting of Ga, In, Al, and Rh. The proportion of the conductive filler to the electromagnetic wave absorption film is equal to or greater than 0.1% by volume and equal to or less than 10% by volume.

### TECHNICAL FIELD

The present disclosure generally relates to an electromagnetic wave absorbing sheet, and more particularly relates to an electromagnetic wave absorbing sheet including a metallic base and an electromagnetic wave absorption film formed on the metallic base.

### BACKGROUND ART

Recently, an increasing number of vehicles are equipped with a collision damage mitigation brake in order to detect any obstacle around them and avoid collision with the obstacle. As sensors for such a collision damage mitigation brake, a millimeter wave radar device, an infrared radar device, and an image recognition device using a camera, for example, have been used. Among other things, a millimeter wave radar device has attracted a lot of attention from the art, because the device of that type is hardly subject to the harmful effects of back lighting, rain, fog, or any other bad condition, and is effectively applicable to capturing an image even at night or even at the time of bad weather when the field of view is usually very narrow.

The millimeter wave radar device detects the location, relative velocity, direction, or any other parameter of the obstacle by mainly using, as an electromagnetic wave transmitted from a transmission antenna (hereinafter referred to as a “transmitted wave”), a radio wave falling within a 76 GHz band (which is equal to or higher than 76 GHz and equal to or lower than 77 GHz) or a 79 GHz band (which is equal to or higher than 77 GHz and equal to or lower than 81 GHz) and by making its reception antenna receive the electromagnetic wave reflected from the obstacle.

Nevertheless, the millimeter wave radar device has some drawbacks. For example, part of the transmitted wave may be internally reflected inside the millimeter wave radar device itself, and the reflected electromagnetic wave (hereinafter referred to as a “direct wave”) may be directly received at the reception antenna. This could increase the chances of the millimeter wave radar device failing to detect pedestrians and other obstacles, because the electromagnetic waves reflected from pedestrians and other obstacles often have very low strength. Thus, to remove such a direct wave, there has been an increasing demand for an electromagnetic wave absorber that achieves a high return loss in a frequency band including a range from 76 GHz to 81 GHz.

Various types of such electromagnetic wave absorbers have been proposed in the art so far. For example, Patent Document 1 teaches that a radio wave absorber including a radio wave absorption film that contains monosubstituted ε-iron oxide and carbon nanotubes would exhibit good radio wave absorptivity even if the radio wave absorption film has a thickness less than 1 mm. Patent Document 2 teaches that a radio wave absorber including a radio wave absorption film that contains trisubstituted ε-Fe₂O₃ and black titanium oxide achieves a high return loss over a broader frequency band width in a frequency band including a range from 76 GHz to 81 GHz. Patent Document 3 teaches that excellent radio wave absorptivity would be achieved in a millimeter wave band by providing multiple radio wave absorption layers. Meanwhile, Patent Document 4 teaches using MTC-substituted ε-iron oxide as a material for the radio wave absorption film. Non-Patent Document 1 teaches using Ga-substituted ε-iron oxide as a material for the radio wave absorption film. Non-Patent Document 2 teaches using Al-substituted ε-iron oxide as a material for the radio wave absorption film. Non-Patent Document 3 teaches using Rh-substituted ε-iron oxide as a material for the radio wave absorption film.

In each of these known electromagnetic wave absorbers, however, the return loss heavily depends on the electromagnetic wave incident angle and a high return loss cannot be achieved in a sufficiently broad electromagnetic wave incident angle range. Thus, none of these known electromagnetic wave absorbers are able to filter out electromagnetic waves coming from various directions.

### CITATION LIST

### Patent Literature

Patent Document 1: JP 2016-111341 A
Patent Document 2: JP 2019-012799 A
Patent Document 3: WO 2018/124131 A1
Patent Document 4: WO 2008/149785 A1

### Non-Patent Literature

Non-Patent Document 1: S. Ohkoshi, S. Kuroki, S. Sakurai, K. Matsumoto, K. Sato, and S. Sasaki, Angew. Chem. Int. Ed., 46, 8392-8395 (2007)
Non-Patent Document 2: A. Namai, S. Sakurai, M. Nakajima, T. Suemoto, K. Matsumoto, M. Goto, S. Sasaki, and S. Ohkoshi, J. Am. Chem. Soc., 131, 1170-1173 (2009)
Non-Patent Document 3: A. Namai, M. Yoshikiyo, K. Yamada, S. Sakurai, T. Goto, T. Yoshida, T. Miyazaki, M. Nakajima, T. Suemoto, H. Tokoro, and S. Ohkoshi, Nature Communications, 3, 1035/1-6 (2012)

### SUMMARY OF INVENTION

The problem to be overcome by the present disclosure is to provide an electromagnetic wave absorbing sheet which achieves a high return loss in a sufficiently broad electromagnetic wave incident angle range.

An electromagnetic wave absorbing sheet according to an aspect of the present disclosure includes a metallic base, and an electromagnetic wave absorption film formed on the metallic base. The electromagnetic wave absorption film contains MTC-substituted ε—Fe₂O₃, black titanium oxide, a conductive filler, and a resin. The MTC-substituted ε—Fe₂O₃ is a crystal belonging to the same space group as an ε—Fe₂O₃ crystal and containing Ti, Co, Fe, and at least one element selected from the group consisting of Ga, In, Al, and Rh. Proportion of the conductive filler to the electromagnetic wave absorption film is equal to or greater than 0.1% by volume and equal to or less than 10% by volume.

An electromagnetic wave absorbing sheet according to another aspect of the present disclosure includes a metallic base, and an electromagnetic wave absorption film formed on the metallic base. The electromagnetic wave absorption film contains MTC-substituted ε-Fe₂O₃, black titanium oxide, and a resin. The MTC-substituted ε—Fe₂O₃ is a crystal belonging to the same space group as an ε—Fe₂O₃ crystal and containing Ti, Co, Fe, and at least one element selected from the group consisting of Ga, In, Al, and Rh. An imaginary part (ε″) of a relative dielectric constant of the black titanium oxide is equal to or greater than 2.0 when the black titanium oxide accounts for 30% by volume of the resin.

### BRIEF DESCRIPTION OF DRAWINGS

FIG. 1A is a schematic front view of an electromagnetic wave absorbing sheet according to a first embodiment of the present disclosure;

FIG. 1B is a schematic cross-sectional view of the electromagnetic wave absorbing sheet taken along the plane Z-Z shown in FIG. 1A;

FIG. 2 is a schematic cross-sectional view illustrating a millimeter wave radar device as an exemplary implementation of the electromagnetic wave absorbing sheet according to the first embodiment of the present disclosure;

FIG. 3A is a schematic front view of an electromagnetic wave absorbing sheet according to a second embodiment of the present disclosure; and

FIG. 3B is a schematic cross-sectional view of the electromagnetic wave absorbing sheet taken along the plane Z-Z shown in FIG. 3A.

### DESCRIPTION OF EMBODIMENTS

### 1. Overview

An electromagnetic wave absorbing sheet according to an exemplary embodiment includes a metallic base, and an electromagnetic wave absorption film formed on the metallic base. The electromagnetic wave absorption film contains MTC-substituted ε-Fe₂O₃, black titanium oxide, and a resin.

The present inventors discovered that there is correlation, in an electromagnetic wave absorbing sheet according to this embodiment, between a high imaginary part ε″ of the relative dielectric constant of particles included in an electromagnetic wave absorption film thereof and an electromagnetic wave incident angle range in which a high return loss was achieved. That is to say, the present inventors discovered that if the electromagnetic wave absorption film contained a conductive filler in addition to the black titanium oxide or if the black titanium oxide itself had a high imaginary part ε″ of the relative dielectric constant thereof, then a high return loss would be achievable and the electromagnetic wave incident angle range in which the high return loss would be achievable could be broadened. The reason is not perfectly clear at this stage but may be presumed as follows. Specifically, using the black titanium oxide makes the imaginary part of the relative dielectric constant of the electromagnetic wave absorption film high enough to cause an increase in the return loss of the electromagnetic wave absorbing sheet. Besides, the imaginary part of the relative dielectric constant of the electromagnetic wave absorption film may be increased efficiently by either adding a conductive filler or using a black titanium oxide, of which the relative dielectric constant has an even higher imaginary part ε″, thus enabling further increasing the return loss. As a result, the electromagnetic wave absorbing sheet would further broaden the electromagnetic wave incident angle range in which the high return loss is achievable. Thus, the present disclosure provides an electromagnetic wave absorbing sheet which achieves a high return loss in a sufficiently broad electromagnetic wave incident angle range.

An electromagnetic wave absorbing sheet according to a first embodiment of the present disclosure (hereinafter referred to as a “first electromagnetic wave absorbing sheet 1”) includes a metallic base and an electromagnetic wave absorption film. The electromagnetic wave absorption film contains MTC-substituted ε—Fe₂O₃, black titanium oxide, a conductive filler, and a resin. The proportion of the conductive filler to the electromagnetic wave absorption film is equal to or greater than 0.1% by volume and equal to or less than 10% by volume.

An electromagnetic wave absorbing sheet according to a second embodiment of the present disclosure (hereinafter referred to as a “second electromagnetic wave absorbing sheet 2”) includes a metallic base and an electromagnetic wave absorption film. The electromagnetic wave absorption film contains MTC-substituted ε—Fe₂O₃, black titanium oxide, and a resin. An imaginary part ε″ of a relative dielectric constant of the black titanium oxide is equal to or greater than 2.0 when the black titanium oxide accounts for 30% by volume of the resin.

The electromagnetic wave absorbing sheet according to this embodiment may broaden an electromagnetic wave incident angle range in which a high return loss is achieved.

### 2. Details

### First Electromagnetic Wave Absorbing Sheet 1

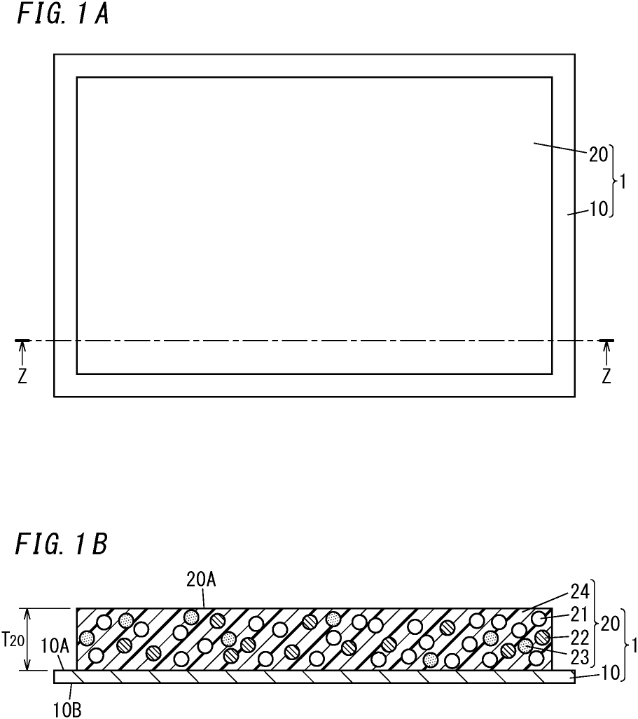

FIG. 1A is a schematic front view of the first electromagnetic wave absorbing sheet 1. FIG. 1B is a schematic cross-sectional view of the first electromagnetic wave absorbing sheet 1 taken along the plane Z-Z shown in FIG. 1A.

The first electromagnetic wave absorbing sheet 1 is a single-layer electromagnetic wave absorbing sheet including a first metallic base 10 and a first electromagnetic wave absorption film 20 as shown in FIGS. 1A and 1B. The first electromagnetic wave absorption film 20 is formed on the first metallic base 10. The first metallic base 10 is made of an electron conductor. The first electromagnetic wave absorption film 20 includes a plurality of MTC-substituted ε—Fe₂O₃ particles 21, a plurality of black titanium oxide particles 22, a plurality of conductive filler particles 23, and a resin 24. The plurality of MTC-substituted ε—Fe₂O₃ particles 21, the plurality of black titanium oxide particles 22, and the plurality of conductive filler particles 23 are dispersed in the resin 24. The MTC-substituted ε—Fe₂O₃ is a crystal belonging to the same space group as an ε—Fe₂O₃ crystal and containing Ti, Co, Fe, and at least one element selected from the group consisting of Ga, In, Al, and Rh. The MTC-substituted ε—Fe₂O₃ is preferably a crystal expressed by the general formula ε-MₓTi_{y}Co_{y}Fe_{2-2y-x}O₃ where M is at least one element selected from the group consisting of Ga, In, Al, and Rh, 0 < x < 1, 0 < y < 1, and x + 2y < 2. As used herein, the “MTC-substituted ε—Fe₂O₃ particle 21” refers to a particle mainly composed of MTC-substituted ε—Fe₂O₃ crystals. The “black titanium oxide particle 22” refers to a particle mainly composed of black titanium oxide crystals. The “black titanium oxide” refers herein to titanium suboxide lacking an oxygen atom with respect to TiO₂ and is expressed by the general formula TiOₓ (where 1 ≤ x < 2). The abundance ratio of crystals may be obtained by the Rietveld analysis based on an X-ray diffraction pattern.

The imaginary part ε″ of the relative dielectric constant of the black titanium oxide particles 22 may or may not be high. As used herein, if “the imaginary part of the relative dielectric constant of the black titanium oxide particles 22 is not high,” then it means that the imaginary part is less than 2.0 when the black titanium oxide particles account for 30% by volume of the resin. The imaginary part ε″ of the relative dielectric constant is preferably equal to or greater than 1.0. The imaginary part ε″ of the relative dielectric constant is more preferably equal to or greater than 1.5 and even more preferably equal to or greater than 1.7. Making the imaginary part of the relative dielectric constant of the black titanium oxide particles 22 high allows the first electromagnetic wave absorbing sheet 1 to further broaden the electromagnetic wave incident angle range in which a high return loss is achieved. The higher the imaginary part ε″ of the relative dielectric constant of the black titanium oxide particles 22 is, the better. It is sufficient that the imaginary part is at most 6.0.

The real part (ε′) of the relative dielectric constant of the black titanium oxide particles 22 is normally equal to or greater than 7.0 and preferably equal to or greater than 8.0 when the black titanium oxide particles 22 account for 30% by volume of the resin. It is sufficient that the real part ε′ of the relative dielectric constant of the black titanium oxide particles 22 is at most 10.0.

The resin for use to measure the relative dielectric constant (i.e., a matrix resin for use to measure the dielectric constant) is not limited to any particular resin but may be, for example, an acrylic resin, an epoxy resin, or a silicone resin.

The first electromagnetic wave absorbing sheet 1 has such a structure, and therefore, its electromagnetic wave incident angle range in which a high return loss is achieved is broader than a known one in a frequency band from 76 GHz to 81 GHz. Therefore, arranging and using the first electromagnetic wave absorbing sheet 1 inside a millimeter wave radar device (of which the transmitted wave has a frequency falling within either the 76 GHz band or the 79 GHz band) as will be described later allows redundant electromagnetic waves, such as the electromagnetic waves internally reflected inside the radar device, to be absorbed sufficiently for the millimeter wave radar device to detect pedestrians and other obstacles easily. As used herein, the frequency band including a range from 76 GHz to 81 GHz just needs to cover at least the range from 76 GHz to 81 GHz and is preferably equal to or higher than 65 GHz and equal to or lower than 95 GHz. A method for measuring the electromagnetic wave incident angle range in which a high return loss is achieved is the same as the method for measuring the “dependence of the return loss on the electromagnetic wave incident angle” to be described later about specific examples.

As used herein, the “high return loss” refers to a return loss equal to or greater than 15 dB, for example. In the first electromagnetic wave absorbing sheet 1, the broader the electromagnetic wave incident angle range in which a return loss equal to or greater than 15 dB is achieved in a frequency range from 76 GHz to 81 GHz is, the better. This range preferably includes a range from 0 degrees to 10 degrees, more preferably includes a range from 0 degrees to 15 degrees, and even more preferably includes a range from 0 degrees to 20 degrees, in the frequency range from 76 GHz to 81 GHz.

The first electromagnetic wave absorbing sheet 1 has a peak of absorption at which the return loss becomes maximum (i.e., a peak of absorption at which the amount of electromagnetic waves absorbed becomes maximum) preferably in the range from 20 GHz to 300 GHz, more preferably in the range from 65 GHz to 95 GHz, and even more preferably in the range from 76 GHz to 81 GHz.

The first electromagnetic wave absorbing sheet 1 preferably has a thickness equal to or greater than 0.1 mm. This allows the first electromagnetic wave absorbing sheet 1 to have an even higher strength. The thickness is more preferably equal to or greater than 0.15 mm and even more preferably equal to or greater than 0.2 mm. Meanwhile, the thickness is preferably equal to or less than 1 mm. In that case, the first electromagnetic wave absorbing sheet 1 is thin enough to be installed and used in a narrow place. The thickness is more preferably equal to or less than 0.95 mm, even more preferably equal to or less than 0.9 mm, and particularly preferably equal to or less than 0.5 mm.

### First Metallic Base 10

The first electromagnetic wave absorbing sheet 1 includes the first metallic base 10. The first electromagnetic wave absorption film 20 is stacked directly on the first metallic base 10.

The first metallic base 10 has the shape of a flat plate or foil with a uniform thickness. The first metallic base 10 has a first surface 10A and a second surface 10B. The first surface 10A is a flat surface. On the first surface 10A, the first electromagnetic wave absorption film 20 is formed. The dimensions of the first metallic base 10 may be adjusted as appropriate according to the intended use of the first electromagnetic wave absorbing sheet 1, for example. The first metallic base 10 preferably has a thickness equal to or greater than 0.1 µm and equal to or less than 5 cm, more preferably has a thickness equal to or greater than 1 µm and equal to or less than 5 mm, and even more preferably has a thickness equal to or greater than 10 µm and equal to or less than 100 µm.

The first metallic base 10 is made of an electron conductor. This allows the first electromagnetic wave absorbing sheet 1 to achieve a greater return loss than a corresponding electromagnetic wave absorbing sheet having the same configuration as the first electromagnetic wave absorbing sheet 1 except that its first metallic base 10 is made of another material, not an electron conductor. This is presumably because of the following reasons. Specifically, when the first electromagnetic wave absorbing sheet 1 is irradiated with electromagnetic waves, some of the electromagnetic waves are reflected from the surface of the first electromagnetic wave absorption film 20 (such electromagnetic waves will be hereinafter referred to as “first reflected waves”), while the other electromagnetic waves propagate inside the first electromagnetic wave absorption film 20, are attenuated by the MTC-substituted ε-Fe₂O₃ and the black titanium oxide, and then reach the surface of the first metallic base 10. The electromagnetic waves are totally reflected by an eddy current generated on the surface of the first metallic base 10 to propagate inside the first electromagnetic wave absorption film 20 again while being attenuated and reach the surface of the first electromagnetic wave absorption film 20 all over again. Some of the electromagnetic waves are reflected from the surface of the first electromagnetic wave absorption film 20 to return to the inside of the first electromagnetic wave absorption film 20, while the other electromagnetic waves are radiated from the surface 20A of the first electromagnetic wave absorption film 20 (such electromagnetic waves will be hereinafter referred to as “second reflected waves”). After that, the electromagnetic waves will be reflected and attenuated over and over again in the same way inside the first electromagnetic wave absorption film 20. Controlling the thickness of the first electromagnetic wave absorption film 20 appropriately allows those reflected waves (including the first reflected waves, the second reflected waves, and so on) to interfere with, and cancel, each other. As can be seen, a high return loss is achievable by attenuating the electromagnetic waves through the repetitive reflections and attenuations inside the first electromagnetic wave absorption film 20 and letting the reflected waves interfere with each other. A metal is suitably used as the electron conductor. Examples of metals include copper, aluminum, titanium, stainless steel (SUS), brass, silver, gold, and platinum. As used herein, the “metal” refers to a substance with a resistivity (at 20° C.) equal to or less than 10⁻⁴ Ω▪ m.

The first metallic base 10 has the first surface 10A with the shape of a flat plate or foil. Forming the first metallic base 10 in the shape of foil allows the first electromagnetic wave absorption film 20 to maintain the flexibility of the first electromagnetic wave absorbing sheet 1 made of the resin 24, thus making the first electromagnetic wave absorbing sheet 1 usable in a folded form. The shape of the first metallic base 10 may be adjusted as appropriate according to the intended use of the first electromagnetic wave absorbing sheet 1, and may have a curved shape, for example. The first surface 10A may have unevenness. In that case, raised portions of the unevenness may have a semicircular, semielliptical, triangular, rectangular, diamond, or hexagonal cross section, for example.

### First Electromagnetic Wave Absorption Film 20

The first electromagnetic wave absorbing sheet 1 includes the first electromagnetic wave absorption film 20. The first electromagnetic wave absorption film 20 transforms part of the energy of the incident electromagnetic waves into thermal energy. That is to say, the first electromagnetic wave absorption film 20 absorbs the electromagnetic waves propagating inside the first electromagnetic wave absorption film 20 itself. The first electromagnetic wave absorption film 20 is formed on the first surface 10A of the first metallic base 10. In this embodiment, the first electromagnetic wave absorbing sheet 1 includes a single-layer first electromagnetic wave absorption film 20. However, this is only an example of this embodiment and should not be construed as limiting. Alternatively, the first electromagnetic wave absorption film 20 may be made up of two or more layers.

The first electromagnetic wave absorption film 20 includes the plurality of MTC-substituted ε-Fe₂O₃ particles 21, the plurality of black titanium oxide particles 22, the plurality of conductive filler particles 23, and the resin 24. The plurality of MTC-substituted ε-Fe₂O₃ particles 21, the plurality of black titanium oxide particles 22, and the plurality of conductive filler particles 23 are dispersed in the resin 24.

The first electromagnetic wave absorption film 20 has a uniform thickness T₂₀. The first electromagnetic wave absorption film 20 has a flat surface 20A. The thickness T₂₀ of the first electromagnetic wave absorption film 20 may be adjusted as appropriate according to the frequency of the electromagnetic waves to absorb and the material of the first electromagnetic wave absorption film 20. In particular, the thickness T₂₀ of the first electromagnetic wave absorption film 20 is preferably the sum of one quarter of the wavelength of the electromagnetic waves to absorb when the electromagnetic waves propagate inside the first electromagnetic wave absorption film 20 and a half of the wavelength multiplied by n, where n is an integer that is equal to or greater than zero, and is preferably equal to or greater than 0 and equal to or less than 3, and more preferably either 0 or 1. In addition, adjusting the thickness T₂₀ of the first electromagnetic wave absorption film 20 enables controlling, for example, the return loss of the first electromagnetic wave absorbing sheet 1, the frequency at which a peak of absorption appears, the bandwidth of the frequency range in which a high return loss is achieved, and the electromagnetic wave incident angle range in which the high return loss is achieved. The thickness T₂₀ of the first electromagnetic wave absorption film 20 may be determined based on a cross-sectional TEM image, observed through a transmission electron microscope (TEM), of the first electromagnetic wave absorption film 20.

Setting the thickness T₂₀ of the first electromagnetic wave absorption film 20 as the sum of one quarter of the wavelength of the electromagnetic waves propagating inside the first electromagnetic wave absorption film 20 and a half of the wavelength multiplied by n may further reduce the electromagnetic waves reflected from the first surface 10A. This should be mainly because the electromagnetic waves reflected from the surface 20A and the electromagnetic waves reflected from the first surface 10A inside of the first electromagnetic wave absorption film 20 and emerging from the surface 20A (hereinafter referred to as “first internally reflected waves”) would have mutually opposite phases, and therefore, would cancel each other by interfering with each other. The first internally reflected waves include not only first-order reflected waves reflected only once from the first surface 10A, but also multi-reflected waves reflected twice or more from the first surface 10A.

The first electromagnetic wave absorption film 20 preferably has a thickness T₂₀ equal to or greater than 0.1 mm. This would further increase the strength of the first electromagnetic wave absorbing sheet 1. T₂₀ is more preferably equal to or greater than 0.15 mm and even more preferably equal to or greater than 0.2 mm. Meanwhile, the thickness T₂₀ is preferably equal to or less than 1 mm. This enables making the first electromagnetic wave absorbing sheet 1 thin enough to be installed and used in a narrow place. T₂₀ is more preferably equal to or less than 0.9 mm and even more preferably equal to or less than 0.5 mm.

The relative dielectric constant of the first electromagnetic wave absorption film 20 has a real part (ε′) which is preferably equal to or greater than 5, and more preferably equal to or greater than 8, at a frequency of 79 GHz, and has an imaginary part (ε″) which is preferably equal to or greater than 2.0, and more preferably equal to or greater than 3.0, at a frequency of 79 GHz.

In the first electromagnetic wave absorbing sheet 1, the surface 20A of the first electromagnetic wave absorption film 20 is a flat surface. However, this is only an example of this embodiment and should not be construed as limiting. Alternatively, the surface 20A of the first electromagnetic wave absorption film 20 may have any other shape that allows the incident electromagnetic waves to enter the first electromagnetic wave absorption film 20 more easily and may have the shape of a pyramid or a wedge, for example. Also, in the first electromagnetic wave absorbing sheet 1 illustrated in FIG. 1A, the first electromagnetic wave absorption film 20 does not cover the first surface 10A of the first metallic base 10 entirely. However, this is only an example of this embodiment and should not be construed as limiting. Alternatively, the first electromagnetic wave absorption film 20 may cover the first surface 10A entirely as well.

### MTC-Substituted ε—Fe₂O₃ Particles 21

The first electromagnetic wave absorption film 20 contains the MTC-substituted ε-Fe₂O₃ particles 21 with one or more compositions. This allows the first electromagnetic wave absorbing sheet 1 to have a high return loss, of which the center absorption frequency is equal to or higher than 30 GHz and equal to or lower than 220 GHz. In particular, the first electromagnetic wave absorbing sheet 1 may have a broader absorption bandwidth than a known electromagnetic wave absorbing sheet containing ε-gallium iron oxide particles.

The MTC-substituted ε—Fe₂O₃ is a crystal belonging to the same space group as an ε—Fe₂O₃ crystal and containing Ti, Co, Fe, and at least one element selected from the group consisting of Ga, In, Al, and Rh. The MTC-substituted ε—Fe₂O₃ is preferably a crystal expressed by ε-MₓTi_{y}Co_{y}Fe_{2-2y-x}O₃, where M is at least one element selected from the group consisting of Ga, In, Al, and Rh, 0 < x < 1, 0 < y < 1, and x + 2y < 2. That is to say, the MTC-substituted ε—Fe₂O₃ crystal is a crystal formed by replacing some Fe sites of the ε—Fe₂O₃ crystal with an element M other than Fe, co-doping the ε—Fe₂O₃ crystal with Ti and Co, and then purifying the ε—Fe₂O₃ crystal. The MTC-substituted ε—Fe₂O₃ crystal is a crystal in which M ions, Ti ions, or Co ions are substituted for some Fe ions of the ε—Fe₂O₃ crystal.

Adjusting the amount of the substituent element M enables controlling the frequency of a peak of absorption, at which the return loss of the first electromagnetic wave absorbing sheet 1 becomes minimum.

The plurality of the MTC-substituted ε—Fe₂O₃ particles 21 may either consist of particles with a single composition or include particles with multiple different compositions. The composition of the MTC-substituted ε—Fe₂O₃ particles 21 may be adjusted as appropriate according to the frequency of the electromagnetic waves to absorb. For example, the MTC-substituted ε—Fe₂O₃ particles 21 may consist of only GTC-substituted ε—Fe₂O₃ particles (where M is Ga) or may include at least one type of particles selected from the group consisting of GTC-substituted ε—Fe₂O₃ particles (where M is Ga), ITC-substituted ε—Fe₂O₃ particles (where M is In), ATC-substituted ε—Fe₂O₃ particles (where M is Al), and RTC-substituted ε—Fe₂O₃ particles (where M is Rh).

The MTC-substituted ε—Fe₂O₃ particles 21 have a spherical shape, which increases the load of the plurality of MTC-substituted ε—Fe₂O₃ particles 21 with respect to the first electromagnetic wave absorption film 20. Although the MTC-substituted ε—Fe₂O₃ particles 21 have a spherical shape in this embodiment, the MTC-substituted ε—Fe₂O₃ particles 21 may have a rod shape, a flat (or compressed) shape, or an irregular shape as well.

The mean particle size of the MTC-substituted ε—Fe₂O₃ particles 21 is preferably large enough to allow the MTC-substituted ε—Fe₂O₃ particles 21 to have a single magnetic domain structure and is more preferably equal to or greater than 5 nm and equal to or less than 200 nm, and even more preferably equal to or greater than 10 nm and equal to or less than 100 nm. The mean particle size of the MTC-substituted ε—Fe₂O₃ particles 21 is obtained by observing a cross section of the first electromagnetic wave absorption film 20 through a transmission electron microscope (TEM) and calculating, based on the TEM image, an area-based average value of the particle sizes of 10 MTC-substituted ε—Fe₂O₃ particles 21.

The content of the MTC-substituted ε—Fe₂O₃ particles 21 is preferably equal to or greater than 5% by volume and equal to or less than 70% by volume, more preferably equal to or greater than 10% by volume and equal to or less than 60% by volume, even more preferably equal to or greater than 10% by volume and equal to or less than 40% by volume, and particularly preferably equal to or greater than 15 % by volume and equal to or less than 30% by volume, with respect to the first electromagnetic wave absorption film 20.

The imaginary part of the relative permeability of the MTC-substituted ε—Fe₂O₃ at a resonant frequency thereof is preferably equal to or greater than 0.01 and more preferably equal to or greater than 0.03.

The real part ε′ of the relative dielectric constant of the MTC-substituted ε—Fe₂O₃ is normally equal to or greater than 2.0, preferably equal to or greater than 3.0, and even more preferably equal to or greater than 4.0, when the MTC-substituted ε—Fe₂O₃ accounts for 30% by volume of the resin. It is sufficient that the real part ε′ of the relative dielectric constant of the MTC-substituted ε—Fe₂O₃ is at most 6.0.

The imaginary part ε″ of the relative dielectric constant of the MTC-substituted ε-Fe₂O₃ is normally greater than 0.0 and preferably equal to or greater than 0.10 when the MTC-substituted ε—Fe₂O₃ accounts for 30% by volume of the resin. The higher the imaginary part ε″ of the relative dielectric constant of the MTC-substituted ε—Fe₂O₃ is, the better. It is sufficient that the imaginary part ε″ of the relative dielectric constant of the MTC-substituted ε-Fe₂O₃ is at most 0.50.

### Black Titanium Oxide Particles 22

The first electromagnetic wave absorption film 20 contains a plurality of black titanium oxide particles 22. This allows the first electromagnetic wave absorbing sheet 1 to achieve a high return loss over a broader frequency bandwidth than a corresponding electromagnetic wave absorbing sheet having the same configuration as the first electromagnetic wave absorbing sheet 1 except that the first electromagnetic wave absorption film 20 thereof does not contain the black titanium oxide particles 22.

The relative dielectric constant of the black titanium oxide particles 22 at a frequency equal to or higher than 75 GHz is preferably equal to or greater than 10, and more preferably equal to or greater than 20. This further broadens the bandwidth of the frequency range in which the first electromagnetic wave absorbing sheet 1 achieves a high return loss in the frequency band including a range from 76 GHz to 81 GHz.

As used herein, the black titanium oxide refers to titanium suboxide lacking an oxygen atom with respect to TiO₂. The lower limit value of x in the general formula TiOₓ (where 1 ≤ x < 2) is preferably equal to or greater than 1, more preferably equal to or greater than 1.2, and even more preferably equal to or greater than 1.5. The upper limit value of x is preferably less than 2, more preferably equal to or less than 1.9, and even more preferably equal to or less than 1.85. Specifically, examples of the black titanium oxide include TiO, Ti₂O₃, λ-Ti₃O₅, γ-Ti₃O₅, β-Ti₃O₅, Ti₄O₇, Ti₅O₉, and Ti₆O₁₁. Among other things, at least one compound selected from the group consisting of Ti₄O₇ and λ-Ti₃O₅ is preferably used in view of their high dielectric constant in the frequency range from 76 GHz to 81 GHz and other considerations.

The black titanium oxide particles 22 have the shape of a coral with an uneven surface. This increases the load of the plurality of black titanium oxide particles 22 with respect to the first electromagnetic wave absorption film 20. In this embodiment, the black titanium oxide particles 22 have a coral shape. However, this is only an example of this embodiment and should not be construed as limiting. Alternatively, the black titanium oxide particles 22 may have, for example, a spherical, flat (or compressed), needlelike, or irregular shape as well.

The mean secondary particle size of the black titanium oxide particles 22 is preferably equal to or greater than 100 nm and equal to or less than 10 µm. As used herein, the mean secondary particle size of the black titanium oxide particles 22 is obtained by observing the shape of a power sample through a scanning electron microscope (SEM) and calculating, based on the SEM image, the average value of the particle sizes.

The content of the black titanium oxide particles 22 is preferably equal to or greater than 5% by volume and equal to or less than 70% by volume, more preferably equal to or greater than 8% by volume and equal to or less than 60% by volume, even more preferably equal to or greater than 10% by volume and equal to or less than 40% by volume, and particularly preferably equal to or greater than 10% by volume and equal to or less than 30% by volume, with respect to the first electromagnetic wave absorption film 20.

### Conductive Filler Particles 23

The first electromagnetic wave absorption film 20 contains a plurality of conductive filler particles 23. This allows the first electromagnetic wave absorbing sheet 1 to have a broader electromagnetic wave incident angle range in which a high return loss is achieved than a corresponding electromagnetic wave absorbing sheet having the same configuration as the first electromagnetic wave absorbing sheet 1 except that the first electromagnetic wave absorption film 20 thereof contains no conductive filler particles 23.

The relative dielectric constant of the conductive filler particles 23 at a frequency equal to or higher than 75 GHz is preferably equal to or greater than 10 and more preferably equal to or greater than 20. This enables further broadening an electromagnetic wave incident angle range in which a high return loss is achieved in a frequency band including a range from 76 GHz to 81 GHz.

The conductive filler particles 23 are selected from various materials having electrical conductivity. Examples of materials for the conductive filler particles 23 include: carbon fillers such as carbon black, carbon nanotubes, carbon micro-coils, and graphite; metallic fillers including metal powders such as aluminum powder and nickel powder and metal nanoparticles; and particles formed by coating a conductive material around a ceramic material or a resin material.

In the first electromagnetic wave absorbing sheet 1, the conductive filler particles 23 have a spherical shape. However, this is only an example of this embodiment and should not be construed as limiting. The conductive filler particles 23 may have, for example, a flat (or compressed), needlelike, or irregular shape as well. Optionally, the conductive filler particles 23 may also be a plurality of primary particles which coagulate or are coupled together to form a secondary particle or a structure, for example.

The mean secondary particle size of the conductive filler particles 23 is preferably equal to or greater than 0.1 µm and equal to or less than 1000 µm and more preferably equal to or greater than 1 µm and equal to or less than 100 µm. The mean secondary particle size of the conductive filler particles 23 is determined by observing the shape of a power sample through a scanning electron microscope (SEM) and calculating, based on the SEM image, the average value of the particle sizes.

The content of the conductive filler particles 23 is preferably equal to or greater than 0.1% by volume and equal to or less than 10% by volume with respect to the first electromagnetic wave absorption film 20. If this content were less than 0.1% by volume, then a high return loss could not be achieved in a sufficiently broad electromagnetic wave incident angle range. Meanwhile, if this content were greater than 10% by volume, then the first electromagnetic wave absorbing sheet 1 could fail to be molded. The content of the conductive filler particles 23 is more preferably equal to or greater than 1% by volume and equal to or less than 9.5% by volume, more preferably equal to or greater than 2% by volume and equal to or less than 9% by volume, even more preferably equal to or greater than 3% by volume and equal to or less than 8.5% by volume, and particularly preferably equal to or greater than 4% by volume and equal to or less than 8% by volume.

The real part ε′ of the relative dielectric constant of the conductive filler particles 23 is normally equal to or greater than 3.0, preferably equal to or greater than 3.5, and even more preferably equal to or greater than 4.0, when the conductive filler particles 23 account for 6.0% by volume of the resin. It is sufficient that the real part ε′ of the relative dielectric constant of the conductive filler particles 23 is at most 6.0.

The imaginary part ε″ of the relative dielectric constant of the conductive filler particles 23 is normally greater than 1.0, preferably equal to or greater than 1.5, and more preferably equal to or greater than 2.0, when the conductive filler particles 23 account for 6.0% by volume of the resin. The higher the imaginary part ε″ of the relative dielectric constant of the conductive filler particles 23 is, the better. It is sufficient that the imaginary part ε″ of the relative dielectric constant of the conductive filler particles 23 is at most 5.0.

### Resin 24

The first electromagnetic wave absorption film 20 contains a resin 24. The resin 24 mainly serves as a binder for bonding the MTC-substituted ε-Fe₂O₃ particles 21, the black titanium oxide particles 22, and the conductive filler particles 23 to the first metallic base 10. Adding the resin 24 to the first electromagnetic wave absorption film 20 imparts flexibility to the first electromagnetic wave absorbing sheet 1, thus allowing the first electromagnetic wave absorbing sheet 1 to be used in a folded form.

### Examples of the Resin 24 Include Thermosetting Resins and Thermoplastic Resins

The thermosetting resin may be any type of resin with the ability to bond the MTC-substituted ε—Fe₂O₃ particles 21, the black titanium oxide particles 22, and the conductive filler particles 23 to the first metallic base 10 by curing with heat. Examples of the thermosetting resins include epoxy resins, silicone resins, acrylic resins, phenolic resins, polyimide resins, unsaturated polyester resins, polyvinyl ester resins, polyurethane resins, melamine resins, cyanate ester resins, isocyanate resins, polybenzoxazole resins, and modified resins thereof. Using any of these thermosetting resins as the resin 24 allows the first electromagnetic wave absorbing sheet 1 to be used advantageously even in high-temperature applications. Among other things, the thermosetting resin preferably includes at least one resin selected from the group consisting of silicone resins, acrylic resins, and epoxy resins, considering that each of these resins may be used advantageously even at an elevated temperature as in onboard applications, for example.

The thermoplastic resin may be any type of resin with the ability to bond the MTC-substituted ε—Fe₂O₃ particles 21, the black titanium oxide particles 22, and the conductive filler particles 23 to the first metallic base 10 by being melted with heat. Examples of the thermoplastic resins include: polyolefins including copolymers of polyethylene, polypropylene, or ethylene and an α-olefin such as 1-butene or 1-octene; vinyl resins such as polyvinyl acetate, polyvinyl chloride, and polyvinyl alcohol; polyamides such as polyamide 66 and polyamide 6; polyimide; polyphenylene sulfide; polyoxymethylene; polyesters such as polyethylene terephthalate and polybutylene terephthalate; polystyrene; styrene copolymers such as a polyacrylonitrile-butadiene-styrene copolymer; polycarbonate; poly ether ether ketone; and fluororesins.

The content of the resin 24 is preferably equal to or greater than 5% by volume and equal to or less than 80% by volume, more preferably equal to or greater than 20% by volume and equal to or less than 70% by volume, and even more preferably equal to or greater than 40% by volume and equal to or less than 65% by volume, with respect to the first electromagnetic wave absorption film 20.

### Additives

The first electromagnetic wave absorption film 20 includes the plurality of MTC-substituted ε—Fe₂O₃ particles 21, the plurality of black titanium oxide particles 22, the plurality of conductive filler particles 23, and the resin 24. However, this is only an example of this embodiment and should not be construed as limiting. If necessary, the first electromagnetic wave absorption film 20 may contain an inorganic substance other than the conductive filler particles 23, an additive, or any other suitable ingredients as well. Examples of the inorganic substance include metal oxides. Examples of the metal oxides include barium titanate, iron oxide, and strontium titanate. Examples of the additives include dispersants, colorants, antioxidants, photostabilizers, metal deactivators, flame retardants, and antistatic agents. Examples of the dispersants include silane coupling agents, titanate coupling agents, zirconate coupling agents, and aluminate coupling agents. These inorganic substances and the additives may have any shape such as a spherical, compressed, needlelike, or fiber shape, for example. The content of the additive may be adjusted appropriately as far as the advantages of this embodiment are not counterbalanced.

### Implementation of First Electromagnetic Wave Absorbing Sheet 1

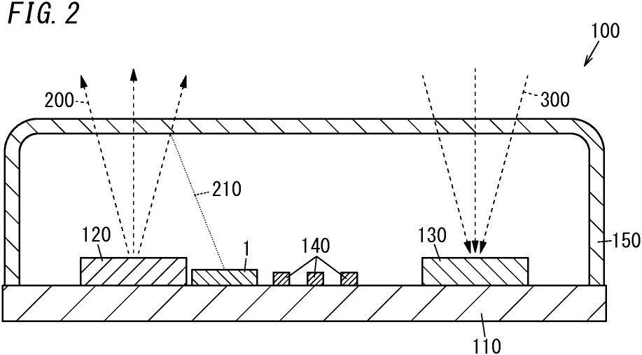

FIG. 2 is a schematic cross-sectional view of a millimeter wave radar device 100 according to a first implementation of the first electromagnetic wave absorbing sheet 1.

The first electromagnetic wave absorbing sheet 1 is preferably used to be arranged inside a millimeter wave radar device 100 as a piece of onboard equipment, for example.

As shown in FIG. 2, the millimeter wave radar device 100 includes a substrate 110, a transmission antenna 120, a reception antenna 130, a circuit 140, a radome 150, and the first electromagnetic wave absorbing sheet 1. The transmission antenna 120, the reception antenna 130, the circuit 140, and the first electromagnetic wave absorbing sheet 1 are arranged on the substrate 110. The circuit 140 is interposed between the transmission antenna 120 and the reception antenna 130 and located closer to the reception antenna 130. The first electromagnetic wave absorbing sheet 1 is interposed between the transmission antenna 120 and the reception antenna 130 and located closer to the transmission antenna 120. The radome 150 covers the transmission antenna 120 and the reception antenna 130.

The millimeter wave radar device 100 detects the location, relative velocity, direction, or any other parameter of the obstacle by transmitting electromagnetic waves 200 from the transmission antenna 120 (hereinafter referred to as “transmitted waves 200”) and receiving the electromagnetic waves 300 reflected from the obstacle (hereinafter referred to as “received waves 300”). The electromagnetic waves 200 preferably include electromagnetic waves with a frequency equal to or higher than 30 GHz and equal to or lower than 300 GHz and particularly preferably fall within the 76 GHz band (from 76 GHz through 77 GHz) or the 79 GHz band (from 77 GHz to 81 GHz). Examples of the obstacles include other vehicles and pedestrians.

This millimeter wave radar device 100 allows some transmitted waves 210, reflected from the radome 150 (hereinafter referred to as “reflected waves 210”), out of the transmitted waves 200 emitted from the transmission antenna 120 to be absorbed into the first electromagnetic wave absorbing sheet 1. The first electromagnetic wave absorbing sheet 1 achieves a high return loss in a broader electromagnetic wave incident angle range than known electromagnetic wave absorbing sheets within the frequency band including a range from 76 GHz to 81 GHz, thus allowing the reflected waves 210 to reach the circuit 140 or the reception antenna 130 less easily than the known electromagnetic wave absorbers. This allows the millimeter wave radar device 100 to detect, with higher sensitivity, any surrounding pedestrians and other obstacles, from which the electromagnetic waves are reflected with low strength, and also reduces the chances of the circuit 140 malfunctioning.

### Method of Making First Electromagnetic Wave Absorbing Sheet 1

A method of making the first electromagnetic wave absorbing sheet 1 includes providing the first metallic base 10 and the first electromagnetic wave absorption film 20 separately and bonding the first metallic base 10 and the first electromagnetic wave absorption film 20 together. Another method of making the first electromagnetic wave absorbing sheet 1 includes providing the first metallic base 10, applying a composition as a material for the electromagnetic wave absorption film onto the first surface 10A of the first metallic base 10, and, for example, thermally curing the composition for the electromagnetic wave absorption film to form the first electromagnetic wave absorption film 20.

Exemplary methods of applying the composition for the electromagnetic wave absorption film include a spray coating method, a dip coating method, a roll coating method, a curtain coating method, a spin coating method, a screen-printing method, a doctor blading method, and an applicator method. The composition for the electromagnetic wave absorption film may be thermally cured by heating the composition for the electromagnetic wave absorption film by a known method, for example.

The composition for the electromagnetic wave absorption film contains at least a powder of the MTC-substituted ε—Fe₂O₃ particles 21, a powder of the black titanium oxide particles 22, a powder of the conductive filler particles 23, and the resin 24 described above. Optionally, to impart flowability that is high enough to allow the first electromagnetic wave absorption film 20 to have any desired thickness, the composition for the electromagnetic wave absorption film may contain a dispersion medium as needed.

Exemplary methods for adjusting the relative permeability of the first electromagnetic wave absorption film 20 thus formed include adjusting the amount to be replaced by the substituent element M in the MTC-substituted ε—Fe₂O₃ and adjusting the content of the powder of the MTC-substituted ε—Fe₂O₃ particles 21 with respect to the first electromagnetic wave absorption film 20. Exemplary methods for adjusting the relative dielectric constant of the first electromagnetic wave absorption film 20 thus formed include adjusting the content of the powder of the black titanium oxide particles 22 and the content of the conductive filler particles 23.

### Powder of MTC-Substituted ε—Fe₂O₃ Particles 21

The powder of the MTC-substituted ε—Fe₂O₃ particles 21 is a collection of the MTC-substituted ε—Fe₂O₃ particles 21. The mean particle size of the powder of the MTC-substituted ε—Fe₂O₃ particles 21 is preferably small enough to cause each particle 21 to have a single magnetic domain structure. The upper limit of the mean particle size of the powder of the MTC-substituted ε—Fe₂O₃ particles 21 is preferably equal to or less than 200 nm, more preferably equal to or less than 100 nm, and even more preferably equal to or less than 18 nm. The lower limit of the mean particle size of the powder of the MTC-substituted ε—Fe₂O₃ particles 21 is preferably equal to or greater than 10 nm and more preferably equal to or greater than 15 nm. Setting the lower limit of the mean particle size of the powder of the MTC-substituted ε—Fe₂O₃ particles 21 within this range reduces the chances of causing deterioration in the magnetic properties per unit mass of the powder of the MTC-substituted ε—Fe₂O₃ particles 21. The mean particle size of the powder of the MTC-substituted ε—Fe₂O₃ particles 21 may be measured by the same method as the one to be described later for specific examples.

### Method of Making Powder of MTC-Substituted ε—Fe₂O₃ Particles 21

An exemplary method of making a powder of the MTC-substituted ε—Fe₂O₃ particles 21 includes the steps of: (a1) obtaining a metal hydroxide by mixing an aqueous solution containing ferric ions such as iron (III) nitrate with a nitric acid aqueous solution containing a metallic element such as Ti, Co, or M as a substituent element and adding an alkali solution such as ammonia water to the mixture; (b1) obtaining a precursor powder by coating the metal hydroxide with a silicone oxide; (c1) obtaining a thermally treated powder by thermally treating the precursor powder in an oxidizing atmosphere; and (d1) subjecting the thermally treated powder to an etching process. In this method, these process steps (a1), (b1), (c1), and (d1) are performed in this order.

### Step (a1)

Step (a1) includes obtaining a metal hydroxide containing iron and a metallic element such as Ti, Co, or M as a substituent element.

An exemplary method for obtaining a metal hydroxide containing iron and a metallic element as a substituent element includes: preparing a dispersion by mixing an iron (III) nitrate nonahydrate, a titanium (IV) sulfate n-hydrate, a cobalt (II) nitrate hexahydrate, and an M compound with pure water; and dripping ammonia aqueous solution into the dispersion and stirring up the mixture. This stirring step causes a metal hydroxide, containing iron and a metallic element such as Ti, Co, or M as a substituent element, to be produced.

As the M compound, for example, a gallium (III) nitrate n-hydrate may be used if M is Ga, an indium (III) nitrate n-hydrate may be used if M is In, an aluminum (III) nitrate n-hydrate may be used if M is Al, and a rhodium (III) nitrate n-hydrate may be used if M is Rh. The amounts of the iron (III) nitrate nonahydrate, the titanium (IV) sulfate n-hydrate, the cobalt (II) nitrate hexahydrate, and the M compound to add may be appropriately adjusted according to the desired composition of the MTC-substituted ε—Fe₂O₃.

If an ammonia aqueous solution is used as an alkaline solution, the amount of the ammonia aqueous solution dripped is, when converted into ammonia, preferably equal to or greater than 3 moles and equal to or less than 30 moles per mole of the iron (III) nitrate. The temperature of the dispersion when the ammonia aqueous solution is dripped into the dispersion is preferably equal to or higher than 0° C. and equal to or lower than 100° C., and more preferably equal to or higher than 20° C. and equal to or lower than 60° C.

### Step (b1)

Step (b1) includes obtaining a precursor powder by coating, with a silicone oxide, the iron (III) nitrate to which the metallic element has been applied. The precursor powder is a collection of particles of the iron (III) nitrate coated with the silicone oxide.

An exemplary method of coating, with the silicone oxide, the iron (III) nitrate to which the metallic element is applied includes, for example, dripping tetraethoxysilane (TEOS) into the dispersion to which the ammonia aqueous solution has been dripped, stirring up the mixture, and then allowing the mixture to cool to room temperature to perform separation treatment.

The amount of the TEOS dripped is preferably equal to or greater than 0.5 moles and equal to or less than 15 moles per mole of the iron (III) nitrate. The stirring is preferably performed for 15 to 30 hours. After the mixture has been allowed to cool, a predetermined amount of precipitant is preferably added thereto. As the precipitant, ammonium sulfate may be used, for example. An exemplary method of performing the separation treatment includes collecting solid matter by sucking and filtering the dispersion to which the TEOS has been dripped and then drying the solid matter thus collected. The drying temperature is preferably about 60° C.

### Step (c1)

Step (c1) includes obtaining a thermally treated powder by thermally treating the precursor powder in an oxidizing atmosphere. As a result, the MTC-substituted ε—Fe₂O₃ particles 21 coated with the silicone oxide are obtained as the thermally treated powder.

The thermal treatment temperature is preferably equal to or higher than 900° C. and lower than 1200° C., and more preferably equal to or higher than 950° C. and equal to or lower than 1150° C. The thermal treatment is preferably conducted for 0.5 to 10 hours, and more preferably for 2 to 5 hours. Examples of the oxidizing atmospheres include the air atmosphere and a mixture of oxygen and nitrogen gases. Among other things, the air atmosphere is preferred out of cost and work efficiency considerations.

### Step (d1)

Step (d1) includes subjecting the thermally treated powder to an etching process, thus removing the silicone oxide from the thermally treated powder and obtaining a collection (powder) of the MTC-substituted ε—Fe₂O₃ particles 21.

An exemplary method of performing the etching process includes pulverizing the thermally treated powder described above, adding the pulverized powder to an aqueous solution of sodium hydroxide (NaOH), and stirring up the mixture. The liquid temperature of the aqueous solution of sodium hydroxide (NaOH) is preferably equal to or higher than 60° C. and equal to or lower than 70° C. The aqueous solution of sodium hydroxide (NaOH) preferably has a concentration of about 5 M. The stirring is preferably performed for 15 to 30 hours.

### Powder of Black Titanium Oxide Particles 22

The powder of the black titanium oxide particles 22 is a collection of the black titanium oxide particles 22. The mean secondary particle size of the powder of the black titanium oxide particles 22 is preferably equal to or greater than 100 nm and equal to or less than 10 µm. An exemplary method of measuring the mean secondary particle size of the powder of the black titanium oxide particles 22 may be the same as the method to be described later for specific examples.

### Method of Making Black Titanium Oxide Particles 22

As the black titanium oxide particles 22, porous Ti₄O₇ particles are preferably used.

An exemplary method of making the porous Ti₄O₇ particles includes, as step (a2), obtaining an aggregate by baking a powder of TiO₂ particles, for example, in a hydrogen atmosphere, and may also include, as step (b2), obtaining porous Ti₄O₇ particles by subjecting the aggregate to a pulverization process as needed.

### Step (a2)

Step (a2) includes obtaining an aggregate by baking a powder of TiO₂ particles in a hydrogen atmosphere. This baking step advances the reduction reaction of the TiO₂ particles. Thus, an aggregate is made of Ti₄O₇ (Ti³⁺₂Ti⁴⁺₂O₇), which is an oxide including Ti³⁺.

The particle size of the TiO₂ particles is preferably equal to or less than 500 nm. Examples of the crystal structure of the TiO₂ particles include an anatase type and a rutile type. The flow rate of the hydrogen gas is preferably equal to or greater than 0.05 L/min and equal to or less than 0.5 L/min, and more preferably equal to or greater than 0.1 L/min and equal to or less than 0.5 L/min. The baking temperature is preferably equal to or higher than 900° C. and equal to or lower than 1200° C., and more preferably equal to or higher than 1000° C. and equal to or lower than 1200° C. The baking temperature is preferably maintained for at most 10 hours, and more preferably for 3 to 7 hours.

### Step (b2)

Step (b2) includes obtaining porous Ti₄O₇ particles by subjecting the aggregate to a pulverization process. This allows porous Ti₄O₇ particles with a desired particle size and a desired shape to be obtained.

Exemplary methods of performing the pulverization process include a ball mill method, a rod mill method, and a crushing pulverization method.

### Dispersion Medium

Any appropriate dispersion medium may be prepared as appropriate according to the material of a composition for the electromagnetic wave absorption film, for example. For example, water, an organic solvent, or an aqueous solution of an organic solvent may be used as the dispersion medium. Examples of the organic solvents include ketones, alcohols, ether alcohols, saturated aliphatic monocarboxylic acid alkyl esters, lactic acid esters, and ether esters. Any of these organic solvents may be used either by itself or in combination. Examples of the ketones include diethyl ketone and methyl butyl ketone. Examples of the alcohols include n-pentanol and 4-methyl-2-pentanol. Examples of the ether alcohols include ethylene glycol monomethyl ether and ethylene glycol monoethyl ether. Examples of the saturated aliphatic monocarboxylic acid alkyl esters include acetate-n-butyl and amyl acetate. Examples of the lactic acid esters include ethyl lactate and lactate-n-butyl. Examples of the ether esters include methyl cellosolve acetate and ethyl cellosolve acetate.

### Second Electromagnetic Wave Absorbing Sheet 2

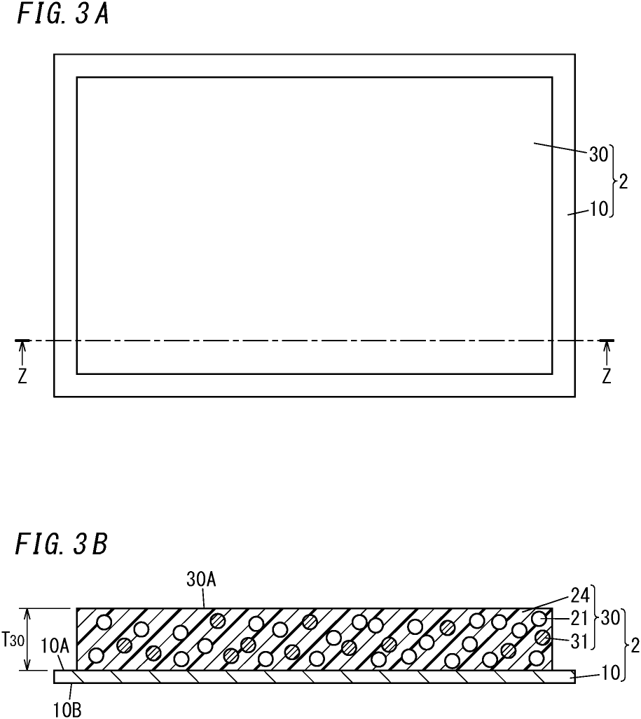

FIG. 3A is a schematic front view of a second electromagnetic wave absorbing sheet 2. FIG. 3B is a schematic cross-sectional view of the second electromagnetic wave absorbing sheet 2 taken along the plane Z-Z shown in FIG. 3A. In FIGS. 3A and 3B, any constituent element of this second electromagnetic wave absorbing sheet 2, having the same function as a counterpart of the first electromagnetic wave absorbing sheet 1 shown in FIGS. 1A and 1B, will be designated by the same reference numeral as that counterpart’s, and description thereof will be omitted herein to avoid redundancies.

The second electromagnetic wave absorbing sheet 2 has the same configuration as the first electromagnetic wave absorbing sheet 1 except that the second electromagnetic wave absorbing sheet 2 contains no conductive fillers and that the imaginary part of the relative dielectric constant of the black titanium oxide is equal to or greater than 2.0 (the particles of such black titanium oxide will be hereinafter referred to as “black titanium oxide particles 31 with high-dielectric-constant imaginary part”) when the black titanium oxide accounts for 30% by volume of the resin. The second electromagnetic wave absorbing sheet 2 includes the black titanium oxide particles 31 with high-dielectric-constant imaginary part, and therefore, may achieve a high return loss in a broader electromagnetic wave incident angle range even though the second electromagnetic wave absorbing sheet 2 contains no conductive fillers.

As shown in FIGS. 3A and 3B, the second electromagnetic wave absorbing sheet 2 is a single-layer electromagnetic wave absorbing sheet including the first metallic base 10 and a second electromagnetic wave absorption film 30. The second electromagnetic wave absorption film 30 is formed on the first metallic base 10. The second electromagnetic wave absorption film 30 includes the plurality of MTC-substituted ε—Fe₂O₃ particles 21, the plurality of black titanium oxide particles 31 with high-dielectric-constant imaginary part, and the resin 24.

The second electromagnetic wave absorbing sheet 2 preferably has a thickness equal to or greater than 0.1 mm. This allows the second electromagnetic wave absorbing sheet 2 to have an even higher strength. The thickness is more preferably equal to or greater than 0.15 mm and even more preferably equal to or greater than 0.2 mm. Meanwhile, the thickness is preferably equal to or less than 1 mm. In that case, the second electromagnetic wave absorbing sheet 2 is thin enough to be installed and used in a narrow place. The thickness is more preferably equal to or less than 0.95 mm, even more preferably equal to or less than 0.9 mm, and particularly preferably equal to or less than 0.5 mm.

### Second Electromagnetic Wave Absorption Film 30

The second electromagnetic wave absorbing sheet 2 includes the second electromagnetic wave absorption film 30. The second electromagnetic wave absorption film 30 transforms part of the energy of the incident electromagnetic waves into thermal energy. That is to say, the second electromagnetic wave absorption film 30 absorbs the electromagnetic waves propagating inside the second electromagnetic wave absorption film 30 itself. The second electromagnetic wave absorption film 30 is formed on the first surface 10A of the first metallic base 10. In this embodiment, the second electromagnetic wave absorbing sheet 2 includes a single-layer second electromagnetic wave absorption film 30. However, this is only an example of this embodiment and should not be construed as limiting. Alternatively, the second electromagnetic wave absorbing sheet 2 may include a second electromagnetic wave absorption film 30 made up of two or more layers.

The second electromagnetic wave absorption film 30 includes the plurality of MTC-substituted ε—Fe₂O₃ particles 21, the plurality of black titanium oxide particles 31 with high-dielectric-constant imaginary part, and the resin 24. The plurality of MTC-substituted ε-Fe₂O₃ particles 21 and the plurality of black titanium oxide particles 31 with high-dielectric-constant imaginary part are dispersed in the resin 24.

The foregoing description about the thickness T₂₀, surface 20A, and other properties of the first electromagnetic wave absorption film 20 is also applicable to the thickness T₃₀, surface 30A, and other properties of the second electromagnetic wave absorption film 30.

The second electromagnetic wave absorption film 30 preferably has a thickness T₃₀ equal to or greater than 0.1 mm. This would further increase the strength of the second electromagnetic wave absorbing sheet 2. T₃₀ is more preferably equal to or greater than 0.15 mm and even more preferably equal to or greater than 0.2 mm. Meanwhile, the thickness T₃₀ is preferably equal to or less than 1 mm. This enables making the second electromagnetic wave absorbing sheet 2 thin enough to be installed and used in a narrow place. T₃₀ is more preferably equal to or less than 0.9 mm and even more preferably equal to or less than 0.5 mm.

The relative dielectric constant of the second electromagnetic wave absorption film 30 has a real part (ε′) which is preferably equal to or greater than 15, and more preferably equal to or greater than 17, at a frequency of 79 GHz, and has an imaginary part (ε″) which is preferably equal to or greater than 2.0, and more preferably equal to or greater than 3.0, at a frequency of 79 GHz.

### Black Titanium Oxide Particles 31 With High-Dielectric-Constant Imaginary Part

The second electromagnetic wave absorption film 30 contains a plurality of black titanium oxide particles 31 with high-dielectric-constant imaginary part.

As used herein, the black titanium oxide with high-dielectric-constant imaginary part refers to titanium suboxide lacking an oxygen atom with respect to TiO₂ and has a relative dielectric constant with an imaginary part (ε″) equal to or greater than 2.0 when the black titanium oxide accounts for 30% by volume of the resin.

The imaginary part ε″ of the relative dielectric constant of the black titanium oxide particles 31 with high-dielectric-constant imaginary part is preferably high. As used herein, if “the imaginary part of the relative dielectric constant of the black titanium oxide particles is high,” then it means that the imaginary part ε″ of the relative dielectric constant is equal to or greater than 2.0 when the black titanium oxide particles account for 30% by volume of the resin. The imaginary part ε″ of the relative dielectric constant of the black titanium oxide particles 31 with high-dielectric-constant imaginary part is preferably equal to or greater than 2.0. The imaginary part ε″ of the relative dielectric constant is more preferably equal to or greater than 3.0 and even more preferably equal to or greater than 4.0. Making the imaginary part of the relative dielectric constant of the black titanium oxide particles 31 with high-dielectric-constant imaginary part high allows the second electromagnetic wave absorbing sheet 2 to further broaden the electromagnetic wave incident angle range in which a high return loss is achieved. The higher the imaginary part ε″ of the relative dielectric constant of the black titanium oxide particles 31 with high-dielectric-constant imaginary part is, the better. It is sufficient that the imaginary part is at most 6.0.

The real part ε′ of the relative dielectric constant of the black titanium oxide particles 31 with high-dielectric-constant imaginary part is normally equal to or greater than 15, preferably equal to or greater than 17, and more preferably equal to or greater than 20, when the black titanium oxide particles with high-dielectric-constant imaginary part account for 30% by volume of the resin. It is sufficient that the real part ε′ of the relative dielectric constant of the black titanium oxide particles with high-dielectric-constant imaginary part is at most 25.0.

The resin for use to measure the relative dielectric constant (i.e., a matrix resin for use to measure the dielectric constant) is not limited to any particular resin but may be, for example, an acrylic resin, an epoxy resin, or a silicone resin.

The relative dielectric constant of the black titanium oxide particles 31 with high-dielectric-constant imaginary part at a frequency equal to or higher than 75 GHz is preferably equal to or greater than 10 and more preferably equal to or greater than 20. This enables further broadening the electromagnetic wave incident angle range in which a high return loss is achieved in a frequency band including a range from 76 GHz to 81 GHz.

The black titanium oxide particles 31 with high-dielectric-constant imaginary part is preferably electrically conductive. As used herein, if the black titanium oxide “is electrically conductive,” it means that its electrical conductivity is equal to or greater than 0.1 S/m, for example. Setting the electrical conductivity of the black titanium oxide with high-dielectric-constant imaginary part at a value equal to or greater than 0.1 S/m allows the second electromagnetic wave absorbing sheet 2 to further broaden the electromagnetic wave incident angle range in which a high return loss is achieved.

The black titanium oxide with high-dielectric-constant imaginary part is expressed by the general formula TiOₓ (where 1 ≤ x < 2 and) where the lower limit of x is preferably equal to or greater than 1, more preferably equal to or greater than 1.2, and even more preferably equal to or greater than 1.5 and the upper limit of x is preferably less than 2, more preferably equal to or less than 1.9, and even more preferably equal to or less than 1.85. Specifically, examples of the black titanium oxide with high-dielectric-constant imaginary part include TiO, Ti₂O₃, λ—Ti₃O₅, γ—Ti₃O₅, β—Ti₃O₅, TL₄O₇, Ti₅O₉, and Ti₆O₁₁. Among other things, the black titanium oxide with high-dielectric-constant imaginary part preferably includes at least one selected from the group consisting of Ti₄O₇ and λ—Ti₃O₅, considering that Ti₄O₇ and λ—Ti₃O₅ each has a high dielectric constant in the frequency range from 76 GHz to 81 GHz.

The black titanium oxide particles 31 with high-dielectric-constant imaginary part have the shape of a coral with an uneven surface. This may increase the load of the plurality of black titanium oxide particles 31 with high-dielectric-constant imaginary part with respect to the second electromagnetic wave absorption film 30. In this embodiment, the black titanium oxide particles 31 with high-dielectric-constant imaginary part have a coral shape. However, this is only an example and should not be construed as limiting. The black titanium oxide particles 31 with high-dielectric-constant imaginary part may have, for example, a spherical, flat (or compressed), needlelike, or irregular shape as well.

The mean secondary particle size of the black titanium oxide particles 31 with high-dielectric-constant imaginary part is preferably equal to or greater than 100 nm and equal to or less than 10 µm. As used herein, the mean secondary particle size of the black titanium oxide particles 31 with high-dielectric-constant imaginary part is determined by observing the shape of a power sample through a scanning electron microscope (SEM) and calculating the average value of the particle sizes based on the SEM image.

The content of the black titanium oxide particles 31 with high-dielectric-constant imaginary part is preferably equal to or greater than 5% by volume and equal to or less than 70% by volume, more preferably equal to or greater than 8% by volume and equal to or less than 60% by volume, even more preferably equal to or greater than 10% by volume and equal to or less than 40% by volume, and particularly preferably equal to or greater than 12% by volume and equal to or less than 25% by volume, with respect to the second electromagnetic wave absorption film 30.

### Implementation of Second Electromagnetic Wave Absorbing Sheet 2

The second electromagnetic wave absorbing sheet 2, as well as the first electromagnetic wave absorbing sheet 1 described above, is preferably used to be arranged inside a millimeter wave radar device 100 as a piece of onboard equipment, for example.

### Method of Making Second Electromagnetic Wave Absorbing Sheet 2

The second electromagnetic wave absorbing sheet 2 may be made by the same method as the first electromagnetic wave absorbing sheet 1 described above.

### Method of Making Black Titanium Oxide Particles 31 With High-Dielectric-Constant Imaginary Part

The black titanium oxide particles 31 with high-dielectric-constant imaginary part may be made by, for example, the same method as the method of making the black titanium oxide particles 22 described above.

### EXAMPLES

Next, the present disclosure will be described in further detail by way of illustrative examples. Note that the examples to be described below are only examples of the present disclosure and should not be construed as limiting.

### 1. Synthesis of Powder of MTC-Substituted ε—Fe₂O₃ Particles

As a powder of MTC-substituted ε—Fe₂O₃ particles 21, an ε-iron oxide powder synthesized in the following manner was used.

First of all, a precursor powder was synthesized by sol-gel process. Specifically, 28 g of iron (III) nitrate nonahydrate, 0.69 g of titanium (IV) sulfate n-hydrate, 0.61 g of cobalt (II) nitrate hexahydrate, and 3.9 g of gallium (II) nitrate n-hydrate were weighed and put into a 1L Erlenmeyer flask. At this time, the amounts of metals were changed such that the sum of the amounts of the metals Fe + Ga + Ti + Co was adjusted to 64.0 mmol. The metal ratio was adjusted with the content of x set at 0.23 for ε—GaₓTi_{0.05}Co_{0.05}Fe_{1.90-x}O₃. First, 1400 mL of pure water was added to an eggplant flask in which all of these metal salts had been introduced. Next, 57.2 mL of 25% by mass ammonia aqueous solution was dripped at a rate of approximately one or two drops per second into the mixture while the mixture was being heated in an oil bus maintained at 30° C., and the mixture was kept stirred up for 30 minutes to co-precipitate a hydroxide. In this manner, a metal hydroxide containing iron and metallic elements Ga, Ti, and Co was obtained.

Thereafter, 52.8 mL of tetraethyl orthosilicate (TEOS) was dripped at a rate of approximately one or two drops per second into the dispersion in which the ammonia aqueous solution had been dripped, and the mixture was kept heated and stirred up for 20 hours, thereby producing silicon dioxide. After the mixture had been stirred up, the produced solid was filtered out through suction and filtering. The produced solid was then transferred to a petri dish and dried at 60° C. for one night to obtain a precursor powder.

The precursor powder thus obtained was then put into a crucible and baked at 1100° C. for 4 hours using an electric furnace within an air atmosphere, thus obtaining a thermally treated powder. At this time, the temperature was increased at a rate of 4° C./min and lowered at a rate of 5° C./min. The respective particles of the thermally treated powder were covered with the silicon dioxide.

Next, a 3 M NaOH aqueous solution was added to the thermally treated powder thus obtained and the mixture was kept heated and stirred up for 24 hours in an oil bus at 65° C., thereby removing the silicon dioxide. Thereafter, the supernatant was removed by centrifugal separation and the solid thus obtained was dried for one night to obtain an ε-iron oxide powder.

The ε-iron oxide powder thus obtained was subjected to an element analysis using an RF inductively coupled plasma (ICP) spectrometer Agilent 7700x (manufactured by Agilent Technologies). The result of the element analysis revealed that Ga: Ti: Co: Fe = 0.23: 0.05: 0.05: 1.67. That is to say, the ε-iron oxide powder thus obtained turned out to be a powder of ε-Ga_{0.23}Ti_{0.05}Co_{0.05}Fe_{1.67}O₃ particles (hereinafter referred to as “GTC-substituted ε—Fe₂O₃ particles”).

A 1,000,000x photograph of the ε-iron oxide powder thus obtained was shot through a transmission electron microscope JEM2000EX (manufactured by JEOL Ltd.) to observe the shape of the respective particles. As a result, it was confirmed that the particles had a spherical shape. In addition, based on this photograph, the longest axis size and shortest axis size of respective particles of the ε-iron oxide powder were measured and their average was calculated to determine a particle size. The average of the particle sizes (i.e., the mean particle size) of at least 100 independent particles of the ε-iron oxide powder was approximately 30 nm.

### 3. Synthesis of Powder of Black Titanium Oxide Particles 22

As a powder of the black titanium oxide particles 22, a black titanium oxide powder synthesized in the following manner was used.

A powder of TiO₂ particles (with a mean particle size of 7 nm and an anatase crystal structure) was baked in a hydrogen atmosphere to obtain an aggregate. The flow rate of the hydrogen gas was 0.3 L/min. The baking temperature was 1000° C., which was maintained for 5 hours. In this manner, a black titanium oxide powder was obtained.

An X-ray diffraction (XRD) pattern of the black titanium oxide powder thus obtained was analyzed. The result of the analysis revealed, from the peaks that appeared, that 99% of Ti₄O₇ was produced and 1% of Ti₃O₅ was produced in the black titanium oxide powder thus obtained. This black titanium oxide powder was regarded as Ti₄O₇ (representing a low-dielectric-constant imaginary part).

### 3. Preparation of Composition for Electromagnetic Wave Absorption Film

Compositions for electromagnetic wave absorption film were obtained by mixing together the powder of the MTC-substituted ε—Fe₂O₃ particles 21 and the powder of the black titanium oxide particles (either the black titanium oxide particles 22 or the black titanium oxide particles 31 with high-dielectric-constant imaginary part) that had been synthesized as described above, the conductive filler particles 23, and the resin 24 to the proportions shown in the following Table 1 with respect to Examples 1, 2, and 3 and Comparative Examples 1 and 2.
Powder of black titanium oxide particles
   Ti₃O₅: product name ENETIA-301 manufactured by Nippon Denko Co., Ltd.;
   Ti₄O₇(with low-dielectric-constant imaginary part): black titanium oxide particles obtained by the synthesis method described above; and
   Ti₄O₇(with high-dielectric-constant imaginary part): product name ENETIA-401 manufactured by Sakai Chemical Industries Co., Ltd.
Conductive filler particles
   Carbon black: product name #3400B manufactured by Mitsubishi Chemical Corporation.
Resin
   Acrylic resin: ester acrylate polymer, product name Teisan Resin, manufactured by Nagase ChemteX Corporation.

### 4. Formation of Electromagnetic Wave Absorbing Sheet

First, the composition for electromagnetic wave absorption film prepared as described above was applied onto a PET film with a thickness of 40 µm and dried at 130° C. for 5 minutes to remove the solvent and thereby form a sheet having a thickness equal to or greater than 100 µm and equal to or less than 140 µm. Two sheets thus formed was stacked one on top of the other and a sheet of copper foil with a thickness of 18 µm was disposed under the two sheets. Then, the stack thus formed was compressed under a pressure of 1.0 MPa at 160° C. for 10 minutes. In this manner, electromagnetic wave absorbing sheets representing Examples 1, 2, and 3 and Comparative Examples 1 and 2 were formed.

### Measurement of Physical Properties

### Measurement of Relative Dielectric Constant

The relative dielectric constants of the MTC-substituted ε—Fe₂O₃, black titanium oxide, and carbon black were measured by the following method.

Three test pieces, each having dimensions of 60 mm x 60 mm, were cut out of three sheets in which either MTC-substituted ε—Fe₂O₃ or black titanium oxide and a resin were mixed at volume ratios of 0: 100, 20: 80, and 30: 70, respectively. Four more test pieces, each having dimensions of 60 mm x 60 mm, were cut out of four sheets in which carbon black and the resin were mixed at volume ratios of 0: 100, 2: 98, 5: 95, and 6: 94, respectively.

These test pieces were propped up perpendicularly between port 1 and port 2 of a vector network analyzer and had their relative dielectric constants (ε′, ε″) at 79 GHz measured by the free space method. In this manner, relative dielectric constants were measured with respect to respective loads of these materials (i.e., respective percentages by volume of these types of particles with respect to the resin). In this case, an acrylic resin (ester acrylate polymer, product name Teisan Resin, manufactured by Nagase ChemteX Corporation) was used as the resin. The relative dielectric constants measured at the respective loads of these materials are shown in the following Table 1.

### Evaluation

### Measurement of Dielectric Constant of Electromagnetic Wave Absorption Film

Test pieces, each having dimensions of 60 mm x 60 mm, were cut out of the respective sheets, to none of which the sheet of copper foil formed as described above had been attached yet. These test pieces were propped up perpendicularly between port 1 and port 2 of a vector network analyzer and the relative dielectric constants (ε′, ε″) of the respective electromagnetic wave absorption films at 79 GHz were measured by the free space method.

### Measurement of Return Loss at Incident Angle of 0 Degrees

The electromagnetic wave absorbing sheets formed as described above were propped up perpendicularly between port 1 and port 2 of a vector network analyzer and had their return losses (dB) measured by the free space method at a frequency (GHz) corresponding to a peak of absorption and at an incident angle of 0 degrees.

### Dependence of Return Loss on Electromagnetic Wave Incident Angle

To estimate the breadth of the electromagnetic wave incident angle range in which a high return loss was achievable, the return losses were measured in the following procedure by the ellipsometry method at respective electromagnetic wave incident angles. Specifically, each of the electromagnetic wave absorbing sheets formed as described above was propped up perpendicularly inside an electromagnetic wave darkroom. The electromagnetic wave transmitted from a transmitter was allowed to be incident on the electromagnetic wave absorbing sheet and the reflected wave was detected by a detector. The angle of incidence and angle of reflection were set at the same angle. The return losses were measured at electromagnetic wave incident angles of 5, 10, and 20 degrees, respectively, in a frequency range from 76 GHz to 81 GHz. Based on the results thus obtained, the respective electromagnetic wave absorbing sheets were graded as follows:
Grade A: if the return loss was equal to or greater than 15 dB over the entire frequency range from 76 GHz to 81 GHz; or
Grade B: if the return loss was less than 15 dB at some frequencies falling within the frequency range from 76 GHz to 81 GHz.

TABLE 1

| | | Type | Relative dielectric constant | | Ex.1 | Ex.2 | Ex.3 | Cmp.1 | Cmp.2 |
|---|---|---|---|---|---|---|---|---|---|
| Composition of electromagnetic wave absorption film (parts by volume) | MTC-substituted ε—Fe₂O₃ | GaTiCo-substituted ε—Fe₂O₃ | 20 vol% | 4.11-0.14i | 23.5 | 20.0 | 23.5 | 10.0 | 15.0 |
| | | | 30 vol% | 4.86-0.16i | | | | | |
| | Black titanium Oxide | Ti₃O₅ | 20 vol% | 6.23-0.49i | 15.0 | | | | |
| | | | 30 vol% | 10.41-1.31i | | | | | |
| | | Ti₄O₇ (low dielectric constant imaginary part) | 20 vol% | 6.16—0.59i | | 18.0 | | 30.0 | 20.0 |
| | | | 30 vol% | 8.90-1.90i | | | | | |
| | | Ti₄O₇ (high dielectric constant imaginary part) | 20 vol% | 10.67-1.07i | | | 19.0 | | |
| | | | 30 vol% | 22.83-4.51i | | | | | |
| | Conductive filler | Carbon black | 5.0 vol% | 4.00-1.76i | 7.0 | 4.5 | 0.0 | 0.0 | 12.0 |
| | | | 6.0 vol% | 4.22-2.09i | | | | | |
| | Resin | Acrylic resin | | | 54.5 | 57.5 | 57.5 | 60.0 | 53.0 |
| | Total | | | | 100.0 | 100.0 | 100.0 | 100.0 | 100.0 |
| Thickness (µm) of electromagnetic wave absorption film | | | | | 190 | 200 | 220 | 240 | - |
| Dielectric constant of electromagnetic wave absorption film | Free space Method | 79 GHz | ε′ | | 25 | 22 | 20 | 15 | Not moldable |
| | | 79 GHz | ε″ | | 4 | 4 | 5 | 2 | |
| Return loss at incident angle of 0° | Free space Method | Peak of absorption (GHz) | | | 79 | 79 | 79 | 79 | |
| | | Return loss (dB) | | | 19 | 22 | 27 | 12 | |
| Dependence of return loss on electromagnetic wave incident angle | Ellipsometry Method | ≤-15 dB over frequency range from 76 GHz to 81 GHz | Incident angle: 5° | | A | A | A | B | |
| | | | Incident angle: 10° | | A | A | A | B | |
| | | | Incident angle: 20° | | A | A | A | B | |

Reference Signs List

| | |
|---|---|
| 1, 2 | Electromagnetic Wave Absorbing Sheet |
| 10 | Metallic Base |
| 20, 30 | Electromagnetic Wave Absorption Film |
| 21 | MTC-Substituted ε-Fe₂O₃ Particle |
| 22 | Black Titanium Oxide Particle |
| 23 | Conductive Filler Particle |
| 24 | Resin |
| 31 | Black Titanium Oxide Particle with High-Dielectric-Constant Imaginary Part |
| 100 | Millimeter Wave Radar Device |
| 110 | Substrate |
| 120 | Transmission Antenna |
| 130 | Reception Antenna |
| 140 | Circuit |
| 150 | Radome |
| 200 | Transmitted Wave |
| 210 | Reflected Wave |
| 300 | Received Wave |

1. An electromagnetic wave absorbing sheet comprising
a metallic base, and
an electromagnetic wave absorption film formed on the metallic base,
the electromagnetic wave absorption film containing
MTC-substituted ε—Fe₂O₃,
black titanium oxide,
a conductive filler, and
a resin,
the MTC-substituted ε—Fe₂O₃ being a crystal belonging to the same space group as an ε—Fe₂O₃ crystal and containing Ti, Co, Fe, and at least one element selected from the group consisting of Ga, In, Al, and Rh,
proportion of the conductive filler to the electromagnetic wave absorption film being equal to or greater than 0.1% by volume and equal to or less than 10% by volume.

2. The electromagnetic wave absorbing sheet of claim 1, wherein
the electromagnetic wave absorbing sheet has a range in which an electromagnetic wave incident angle causing a return loss equal to or greater than 15 dB is equal to or greater than 0 degrees and equal to or less than 20 degrees over a frequency range from 76 GHz to 81 GHz.

3. The electromagnetic wave absorbing sheet of claim 1, wherein
the electromagnetic wave absorption film has a thickness equal to or greater than 0.1 mm and equal to or less than 0.5 mm.

4. The electromagnetic wave absorbing sheet of claim 1, wherein
the MTC-substituted ε—Fe₂O₃ is expressed by ε-MₓTi_{y}Co_{y}Fe_{2-2y-x}O₃ where M is at least one element selected from the group consisting of Ga, In, Al, and Rh, 0 < x < 1, 0 < y < 1, and x + 2y < 2.

5. The electromagnetic wave absorbing sheet of claim 1, wherein
the black titanium oxide includes at least one compound selected from the group consisting of Ti₄O₇ and λ—Ti₃O₅.

6. The electromagnetic wave absorbing sheet of claim 1, wherein
the resin includes at least one resin selected from the group consisting of silicone resins, acrylic resins, and epoxy resins.

7. An electromagnetic wave absorbing sheet comprising
a metallic base, and
an electromagnetic wave absorption film formed on the metallic base,
the electromagnetic wave absorption film containing
MTC-substituted ε—Fe₂O₃,
black titanium oxide, and
a resin,
the MTC-substituted ε—Fe₂O₃ being a crystal belonging to the same space group as an e-Fe₂O₃ crystal and containing Ti, Co, Fe, and at least one element selected from the group consisting of Ga, In, Al, and Rh,
an imaginary part of a relative dielectric constant of the black titanium oxide being equal to or greater than 2.0 when the black titanium oxide accounts for 30% by volume of the resin.

8. The electromagnetic wave absorbing sheet of claim 7, wherein
the electromagnetic wave absorbing sheet has a range in which an electromagnetic wave incident angle causing a return loss equal to or greater than 15 dB is equal to or greater than 0 degrees and equal to or less than 20 degrees over a frequency range from 76 GHz to 81 GHz.

9. The electromagnetic wave absorbing sheet of claim 7, wherein
the electromagnetic wave absorption film has a thickness equal to or greater than 0.1 mm and equal to or less than 0.5 mm.

10. The electromagnetic wave absorbing sheet of claim 7, wherein
the MTC-substituted ε—Fe₂O₃ is expressed by ε-MₓTi_{y}Co_{y}Fe_{2-2y-x}O₃ where M is at least one element selected from the group consisting of Ga, In, Al, and Rh, 0 < x < 1, 0 < y < 1, and x + 2y < 2.

11. The electromagnetic wave absorbing sheet of claim 7, wherein
the black titanium oxide includes at least one compound selected from the group consisting of Ti₄O₇ and λ—Ti₃O₅.

12. The electromagnetic wave absorbing sheet of claim 7, wherein
the resin includes at least one resin selected from the group consisting of silicone resins, acrylic resins, and epoxy resins.
